(19) United States
(12) Patent Application Publication
(10) Pub. No.: US 2010/0314973 A1
(43) Pub. Date: Dec. 16, 2010

(54) Piezoelectric Device with Magnetically Enhanced Piezoelectricity

(75) Inventor: Wei-Hsiang Wang, Hsinchu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: Ritek Corporation, Hsinchu (TW)

(21) Appl. No.: 12/481,810

(22) Filed: Jun. 10, 2009

(51) Int. Cl. H01L 41/047

(52) U.S. Cl. 310/364

(57) ABSTRACT

A piezoelectric device is disclosed. The piezoelectric device includes a first magnetic layer, a second magnetic layer and a piezoelectric layer. The piezoelectric layer is disposed between the first magnetic layer and the second magnetic layer. Both the first magnetic layer and the second magnetic layer are electrically conductive layers and are capable of generating magnetic fields.

### BACKGROUND

1. Field of Invention

The present invention relates generally to the field of piezoelectric devices. More particularly, the present invention relates to piezoelectric devices with magnetically enhanced piezoelectricity.

2. Description of Related Art

Piezoelectric materials are utilized in actuators, piezoelectric sensors, and other applications. Materials that are capable of generating an electric potential in response to an applied mechanical stress are generally classified as materials having piezoelectricity, or are termed as piezoelectric materials. Piezoelectric materials, such as lead zirconate titanate (PZT) and lead lanthanum zirconate titanate (PLZT), are typically used in actuators or piezoelectric sensors.

Actuators using a piezoelectric material are expected to have various applications, however, a layer of 10 μm piezoelectric material typically requires a driving voltage of about 100 V. This high driving voltage requirement poses a difficulty in implementing piezoelectric elements in various fields.

Recently, a thin film made of a piezoelectric element is disclosed, the thin film actuator comprising the piezoelectric element is small in size, and can be driven by a lower voltage, and generates a larger amount of displacement (See U.S. Pat. No. 7,006,334). Also, a multi-layer structure made of the piezoelectric material is employed to improve the productivity of the actuators and to prevent short-circuiting problems. However, the piezoelectricity coefficients, such as the effective displacement (d₃₃) and the effective charge (e₃₁) of the material used in the actuator is not substantially improved, and thus the piezoelectricity is still not sufficient for other practical applications.

Typical piezoelectric material such as lead zirconate titanate (PZT) has an effective displacement (d₃₃) of about 419 pm/V and an effective charge (e₃₁) in the range of −4.7 to −7.5 C/m². If the effective displacement and effective charge can be increased, it would increase the possibility of implementing the piezoelectric elements in various applications. Therefore, there exists in this art a need of improving the effective displacement and the effective charges of a piezoelectric device with enhanced piezoelectricity.

### SUMMARY

The present invention provides a piezoelectric device having magnetically enhanced piezoelectricity. The device includes a first magnetic layer, a piezoelectric layer and a second magnetic layer. The first and the second magnetic layer are capable of generating a first and a second magnetic field, respectively. The piezoelectric layer is disposed between the first and the second magnetic layer, and both the first and the second magnetic layers are electrically conductive layers. In one embodiment, the first magnetic layer has a first magnetization in a first direction and the second magnetic layer has a second magnetization in a second direction, and the first direction is opposite to the second direction.

According to one embodiment of the present invention, the piezoelectric device further includes a first non-magnetic layer disposed below the first magnetic layer and a second non-magnetic layer disposed above the second magnetic layer. Both the first and the second non-magnetic layer are made of a metal respectively selected from the group consisting of Cu, Ag, Au, Ti, Ta, and Cr. The piezoelectric device may further include a third magnetic layer disposed below the first non-magnetic layer and a fourth magnetic layer disposed above the second non-magnetic layer.

According to another embodiment of the present invention, the piezoelectric device further includes an upper magnetic structure disposed above the second magnetic layer and a lower magnetic structure disposed below the first magnetic layer, wherein the upper magnetic structure and the lower magnetic structure respectively having a super lattice structure comprising a plurality of magnetic layers and a plurality of non-magnetic layers, in which each of the magnetic layer and each of the non-magnetic layer are alternately arranged.

In the present invention, each of the magnetic layers generates a magnetic field that respectively interacts with the piezoelectric layer and thereby increasing the effective displacement and the effective charges generated therein, and results in a decrease in the driving voltage of the actuator using the piezoelectric device of the present invention. Also, a higher sensitivity can be achieved while the piezoelectric device of the present invention is utilized in a piezoelectric sensor. As a result, the piezoelectric elements can be implemented into many applications.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic cross-sectional view of a piezoelectric device according to one embodiment of the present invention;

FIG. 2A is a schematic cross-sectional view of a piezoelectric device according to another embodiment of the present invention;

FIG. 2B is a schematic cross-sectional view of a piezoelectric device according to another embodiment of the present invention; and

FIG. 3 is a schematic cross-sectional view of a piezoelectric device according to another embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

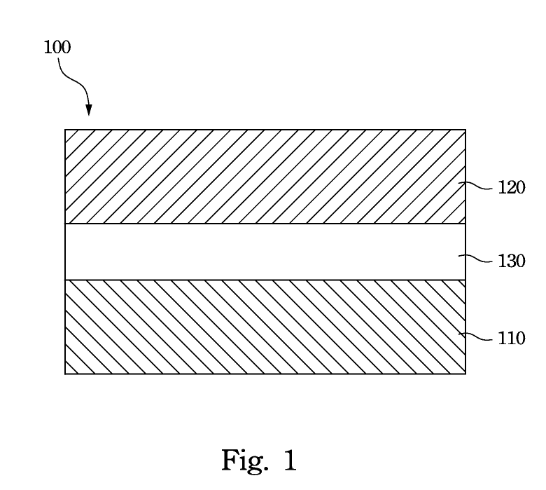

Referring to FIG. 1, which is a schematic cross-sectional view of a piezoelectric device 100 according to one embodiment of the present invention. The piezoelectric device 100 includes a first magnetic layer 110, a second magnetic layer 120, and a piezoelectric layer 130, in which both the first magnetic layer 110 and the second magnetic layer 120 are electrically conductive layers. The piezoelectric layer 130 is disposed between the first magnetic layer 110 and the second magnetic layer 120.

The first magnetic layer 110 is capable of generating a first magnetic field and has a first magnetization in a first direction. For example, the first magnetic layer 110 can be made of a ferromagnetic material. Suitable materials for making the first magnetic layer 110 include, but are not limited to, (Ni,Fe,Co) family, CoCr(Pt,Ta,Ni,B,Si,O,SiO₂) family, (Pr,Nd,Pm,Sm,Eu,Gd,Tb,Dy,Ho,Er)(Ni,Fe,Co)(Cr,N,Ta,Ti,O,Al,B,Mo) family, (Ni,Fe,Co,ir,Pt)Mn family, Nd(Ni,Fe,Co)B family, (Ba,Ni,Fe,Co,Mn,Zn,Y,Mg,Zn,Cd)-oxide family, (Pr,Nd,Pm,Sm,Eu,Gd,Tb,Dy,Ho,Er,Al,Ni,Pt,Pd,Si)Co family, and (Pr,Nd,Pm,Sm,Eu,Gd,Tb,Dy,Ho,Er,Al,Ni,Pt,Pd,Si)Fe family. More specifically, the ferromagnetic material comprises at least one metal selected from the group consisting of Fe, Co, and Ni.

The first magnetic layer 110 can be formed by any well-known technique that includes, but is not limited to, sputtering, thermo-evaporation, ion-beam assisted evaporation, e-beam evaporation, ion-beam deposition, pulsed laser deposition, or other technologies suitable for forming the first magnetic layer 110. For instance, the first magnetic layer 110 can be deposited on an appropriate substrate such as glass, ceramic or semiconductor wafer using suitable targets in an argon environment by sputtering.

After the first magnetic layer 110 is formed, an external magnetic filed is applied to the first magnetic layer 110 to initialize the magnetization of the first magnetic layer 110 in one specific direction, which is the direction of the easy axis anisotropy and is usually determined by the properties of the material. In general, the direction of the easy axis anisotropy of a specific material can be estimated by experiments. After the magnetic initialization, the first magnetic layer 110 has a magnetization in a first direction and is capable of generating a first magnetic field.

In one embodiment, the first magnetic layer 120 is formed by sputtering a material having a formula of Niₙ(Fe_{y}Co_{1-y})₁₋ₙ, wherein y is a number from 0 to 1, and n is a number from 0 to 1. For example, the y value may be controlled by the composition of the Fe/Co target, and the n value is controlled by the process parameters such as power supplies. In the case when y equals to 0, the Fe/Co target becomes a pure Co target and this pure Co target is then used with a pure Ni target in the sputtering step; and when y equals to 1, the Fe/Co target is a pure Fe target and this pure Fe target is then used with a pure Ni target in the sputtering step. In the case when n equals to 0, then only a Fe/Co target is used in the sputtering step, and when n equals to 1, that means only a pure Ni target is used in the sputtering. In one embodiment, a layer of Ni—Fe—Co alloy about 50 nm in thickness with a formula of Ni_{0.2}(Fe_{0.8}Co_{0.2})_{0.8} is deposited on a substrate in an argon environment by sputtering. During the sputtering process, a pure Ni target and a Fe/Co target containing 80 atom % of iron and 20 atom % of cobalt are utilized simultaneously. It is to be noted that the present invention is not limited to the above-mentioned procedure. A Ni—Fe—Co target containing 20 atom % of nickel, 64 atom % of iron and 16 atom % of cobalt can also be used in the sputtering, and the deposited Ni—Fe—Co layer has the composition of Ni_{0.2}(Fe_{0.8}Co_{0.2})_{0.8}. In one embodiment, the first magnetic layer 120 has a magnetization of about 600-2000 emu/cm³ after the magnetic initialization.

In another embodiment, the first magnetic layer 110 is formed by sputtering a material having a formula of Ndₓ(Fe_{y}Co_{1-y})₁₋ₓ, wherein x is a number from about 0.1 to about 0.35, and y is a number from 0 to 1. That is, the first magnetic layer 110 contains about 10-35 atom % of Nd, and about 65-90 atom % of iron and cobalt. In this embodiment, one Fe/Co target and one Nd target are simultaneously utilized during the sputtering process. However, in the case when y in the Fe/Co target equals to 0, the Fe/Co target becomes a pure Co target, and this pure Co target is used with a pure Nd target in the sputtering process. In the case when y equals to 1, that means a pure Fe target and a pure Nd target are used in the sputtering step. In one embodiment, a Nd—Fe—Co layer about 100 nm in thickness and has a structure having a formula of Nd_{0.25}(Fe_{0.8}Co_{0.2})_{0.75} is obtained by controlling the process parameters such as power supplies. It is to be noted that the present invention is not limited to the above-mentioned procedure. A Nd—Fe—Co target containing 25 atom % of neodymium, 60 atom % of iron and 15 atom % of cobalt can also be used in the sputtering and the deposited Nd—Fe—Co layer has the composition of Nd_{0.25}(Fe_{0.8}Co_{0.2})_{0.75}. In one embodiment, the first magnetic layer 110 has a magnetization of about 800-2500 emu/cm³ after the magnetic initialization.

In still another embodiment, the first magnetic layer 110 is an alloy formed by sputtering and has a formula of Tbₘ(Fe_{y}Co_{1-y})₁₋ₘ, wherein m is a number from about 0.1 to about 0.22 and from about 0.25 to about 0.35, and y is a number from 0 to 1. For example, the magnetic layer 220 may have a formula of Tb_{0.21}(Fe_{0.80}Co_{0.20})_{0.79}. In one embodiment, the first magnetic layer 110 has a magnetization of about 60-600 emu/cm³ after the magnetic initialization.

There is no specific limitation on the thickness of the first magnetic layer 110, but typically it can be in the range of about 1 nm to about 200 nm. Specifically, the thickness of the first magnetic layer 110 is between about 20-150 nm.

The piezoelectric layer 130 comprising a piezoelectric material is disposed above the first magnetic layer 110. The term “piezoelectric material” herein represents materials that are capable of generating an electric potential in response to applied mechanical stress. Suitable piezoelectric material for making the piezoelectric layer 130 includes, but is not limited to, silicon dioxide (SiO₂), titanium dioxide (TiO₂), barium titanate (BaTiO₃), lead titanate (PbTiO₃), lead zirconate titanate (PZT), aluminum nitride (AlN), zinc oxide (ZnO) and lead lanthanum zirconate titanate (PLZT). In one embodiment, a layer of PZT can be deposited using a PZT target in an argon environment by sputtering. In another embodiment, a layer of barium titanate (BTO) about 200 nm in thickness is deposited on the first magnetic layer 110 using a BTO target in an argon (Ar) environment by sputtering.

The thickness of the piezoelectric layer 130 can be adjusted depending on various applications. In one embodiment, the piezoelectric layer 130 has a thickness in the range of about 5 nm to about 300 nm.

The second magnetic layer 120 is disposed above the piezoelectric layer 130, and therefore the piezoelectric layer 130 is sandwiched between the first magnetic layer 110 and the second magnetic layer 120. The second magnetic layer 120 has a second magnetization in a second direction and is capable of generating a second magnetic field. In one embodiment, the second direction of the second magnetic layer 120 is different from the first direction of the first magnetic layer 110. In another embodiment, the second direction of the second magnetic layer 120 is opposite to the first direction of the first magnetic layer 110. In still another embodiment, the second direction of the second magnetic layer 120 is identical to the first direction of the first magnetic layer 110.

Suitable materials for making the second magnetic layer 120 include, but are not limited to, (Ni,Fe,Co) family, CoCr(Pt,Ta,Ni,B,Si,O,SiO₂) family, (Pr,Nd,Pm,Sm,Eu,Gd,Tb,Dy,Ho,Er)(Ni,Fe,Co)(Cr,N,Ta,Ti,O,Al,B,Mo) family, (Ni,Fe,Co,Ir,Pt)Mn family, Nd(Ni,Fe,Co)B family, (Ba,Ni,Fe,Co,Mn,Zn,Y,Mg,Zn,Cd)-oxide family, (Pr,Nd,Pm,Sm,Eu,Gd,Tb,Dy,Ho,Er,Al,Ni,Pt,Pd,Si)Co family, and (Pr,Nd,Pm,Sm,Eu,Gd,Tb,Dy,Ho,Er,Al,Ni,Pt,Pd,Si)Fe family. The material of the second magnetic layer 120 may be the same as or different from the material of the first magnetic layer 110. In one embodiment, the first magnetic layer 110 is made of an Nd—Fe—Co alloy, while the second magnetic layer 120 is made of a Ni—Fe—Co alloy. In another embodiment, the first magnetic layer 110 and the second magnetic layer 120 are made of a Ni—Fe—Co alloy, but having different composition. For example the first magnetic layer 110 is made of an Ni—Fe—Co alloy having a formula of Nd_{0.25}(Fe_{0.8}Co_{0.2})_{0.75}, and the second magnetic layer 120 is made of an Ni—Fe—Co alloy having a formula of Nd_{0.1}(Fe_{0.25}Co₇₅)_{0.9}. The method of preparing the second magnetic layer can be similar with the procedure of the first magnetic layer 110 described above.

From the description above, each of the first magnetic layer 110 and the second magnetic layer 120 may generate a magnetic field that interacts with the piezoelectric material in the piezoelectric layer 130. The piezoelectricity coefficients such as the effective displacement (d₃₃) and the effective charge (e₃₁) generated therein can be enhanced by the magnetic fields generated from the first magnetic layer 110 and the second magnetic layer 120.

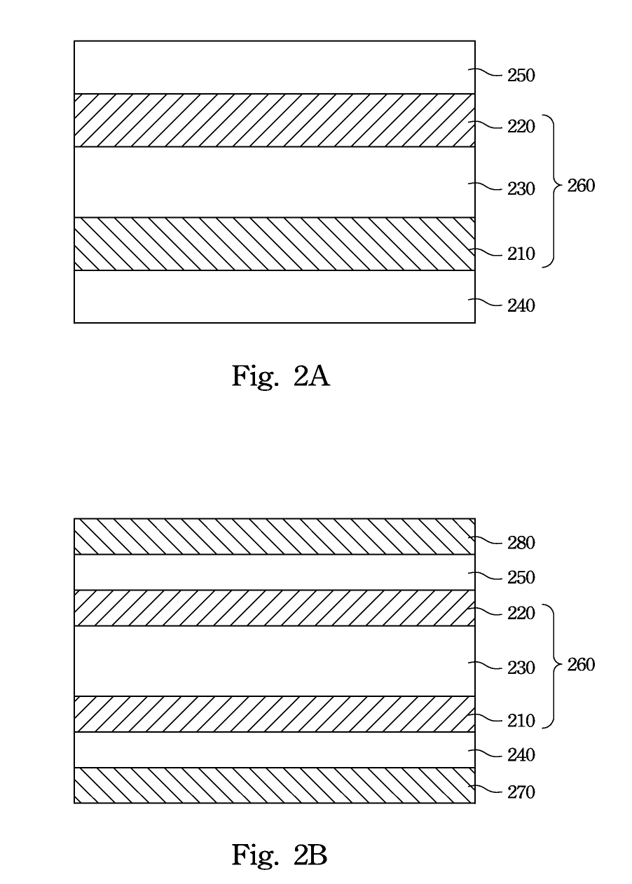

Referring to FIG. 2A, which is a schematic cross-sectional view of a piezoelectric device 200 according to another embodiment of the present invention. The piezoelectric device 200 includes a first non-magnetic layer 240, a second non-magnetic layer 250 and a core structure 260, in which the core structure 260 comprises a first magnetic layer 210, a second magnetic layer 220, and a piezoelectric layer 230. The core structure 260 has a structure that is identical to the piezoelectric device 100 in FIG. 1 as described above. The first non-magnetic layer 240 is disposed below the first magnetic layer 210, and the second non-magnetic layer 250 is disposed above the second non-magnetic layer 220. In this embodiment, both the first non-magnetic layer 240 and the second non-magnetic layer 250 are electrically conductive layers.

In one embodiment, the first non-magnetic layer 240 and the second non-magnetic layer 250 can be made of a metal selected from the group consisting of Cu, Ag, Au, Ti, Ta, Ta, and Cr. The thickness of the first non-magnetic layer 240 or the second non-magnetic layer 250 can be in the range of from about 3 nm to about 10 μm, for example. Thin film processes such as various physical depositions or thick-film processes such as screen-printing can be utilized to form the first non-magnetic layer 240 and the second non-magnetic layer 250, respectively, depending on the desired thickness. In one embodiment, either the first non-magnetic layer 240 or the second non-magnetic layer 250 or the combination thereof may be used as an electrode pad for wiring.

The piezoelectric device 200 may further comprise a third magnetic layer 270 disposed below the first non-magnetic layer 240, and a fourth magnetic layer 280 disposed above the second non-magnetic layer 250, as shown in FIG. 2B. The third magnetic layer 270 has a third magnetization in a third direction and is capable of generating a third magnetic field. Similarly, the fourth magnetic layer 270 has a fourth magnetization in a fourth direction and is capable of generating a fourth magnetic field. In one embodiment, both the third direction of the third magnetic layer 270 and the second direction of the second magnetic layer 220 are opposite to the first direction of the first magnetic layer 210, and the fourth direction of the fourth magnetic layer 280 is identical to the first direction of the first magnetic layer 210.

In one embodiment, both the third and second magnetic layer 220, 270 are made of the same material. In another embodiment, the fourth and the first magnetic layer 210, 280 are made of the same material. The third and fourth magnetic layer 270, 280 can be formed by the process that is similar to the first magnetic layer 210 describe hereinbefore. There is no specific limitation on the thickness of the third and the fourth magnetic layer 270, 280, but typically it can be in the range of about 1 nm to about 200 nm. Specifically, the thickness of the third and/or fourth magnetic layer can be about 20-150 nm.

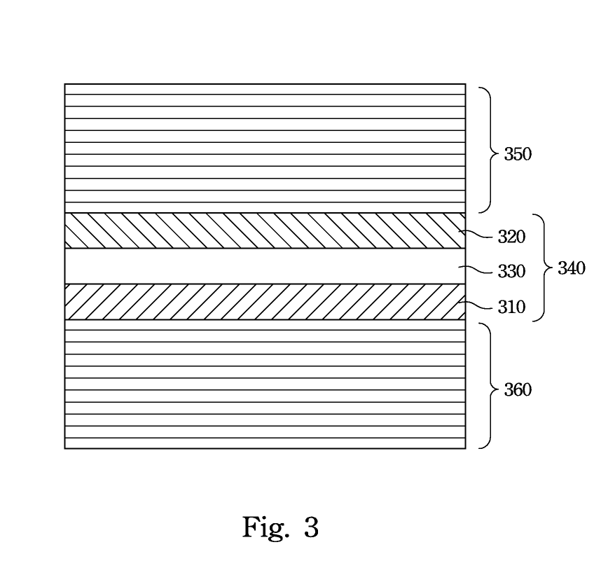

Referring to FIG. 3, which is a schematic cross-sectional view of a piezoelectric device 300 according to another embodiment of the present invention. The piezoelectric device 300 comprises a core structure 340, an upper magnetic structure 350 and a lower magnetic structure 360. The core structure 340 is identical to the piezoelectric device 100 described hereinbefore, and comprises a first magnetic layer 310, a second magnetic layer 320 and a piezoelectric layer 330. The upper magnetic structure 350 is disposed above the second magnetic layer 320, and the lower magnetic structure 350 is disposed below the first magnetic layer 310.

The upper magnetic structure 350 has a supper lattice structure and is capable of generating a magnetic field. The supper lattice structure comprises a plurality of magnetic layers and a plurality of non-magnetic layers, in which each of the magnetic layer and the non-magnetic layer are alternately arranged. All of the magnetic layers and the non-magnetic layers are electrically conductive layers. The magnetic layer can have a magnetization after magnetization initialization, but the non-magnetic layer is devoid of magnetization. In one embodiment, the magnetic layers of the upper magnetic structure 350 are made of Fe, Co, Ni, Fe—Co alloy, Fe—Ni alloy or Fe—Co—Ni alloy, and the non-magnetic layers are made of Cu, Ag, Au, Ti, Ta, Ta, or Cr. In another embodiment, the magnetic layers are made of a material having a formula of Ndₓ(Fe_{y}Co_{1-y})₁₋ₓ, wherein x is a number from about 0.1 to about 0.35, and y is a number from 0 to 1. In still another embodiment, the magnetic layers are made of a material having a formula of Tbₘ(Fe_{y}Co_{1-y})₁₋ₘ, wherein m is a number from about 0.10 to about 0.22 and from about 0.25 to about 0.35, and y is a number from 0 to 1.

The lower magnetic structure 360 also has a supper lattice structure comprising a plurality of magnetic layers and a plurality of non-magnetic layers, in which the magnetic layer and the non-magnetic layer are alternately arranged. In one embodiment, lower magnetic structure 360 is in a mirror-symmetrical relationship with respect to the upper magnetic structure 350. In another embodiment, the material of the magnetic layers and the non-magnetic layer in the lower magnetic structure 350 are different from that in the upper magnetic structure 350. In still another embodiment, the material of the magnetic layer and the non-magnetic layer in the lower magnetic structure 360 are the same material as that of the upper magnetic structure 350.

Each of the upper magnetic structure 350 and the lower magnetic structure 360 may provide a magnetic field that interacts with the piezoelectric material in the piezoelectric layer 330. The piezoelectricity coefficients such as the effective displacement (d₃₃) and the effective generated charge (e₃₁) of the piezoelectric layer 330 can be increased by the magnetic fields generated form the upper magnetic structure 350 and the lower magnetic structure 360. Therefore, the driving voltage of actuators using the piezoelectric device according to the present invention can be decreased. Furthermore, higher accuracy and/or precision can be achieved for applications in piezoelectric sensors or others.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A piezoelectric device, comprising:
a first magnetic layer capable of generating a first magnetic field;
a piezoelectric layer disposed above the first magnetic layer ; and
a second magnetic layer capable of generating a second magnetic field and disposed above the piezoelectric layer;
wherein both the first magnetic layer and the second magnetic layer are electrically conductive layers.

2. The piezoelectric device according to claim 1, further comprising a first non-magnetic layer disposed below the first magnetic layer.

3. The piezoelectric device according to claim 2, wherein the first non-magnetic layer is made of a metal selected from the group consisting of Cu, Ag, Au, Ti, Ta, Ta and Cr.

4. The piezoelectric device according to claim 2, wherein the first non-magnetic layer has a thickness ranges from about 3 nm to about 10 μm.

5. The piezoelectric device according to claim 2, further comprising a second non-magnetic layer disposed above the second magnetic layer.

6. The piezoelectric device according to claim 5, wherein the first magnetic layer has a first magnetization in a first direction and the second magnetic layer has a second magnetization in a second direction, and the first direction is opposite to the second direction.

7. The piezoelectric device according to claim 5, further comprising a third magnetic layer disposed below the first non-magnetic layer, wherein the third magnetic layer is capable of generating a third magnetic field and has a third magnetization in a third direction, and the third direction is opposite to the first direction.

8. The piezoelectric device according to claim 5, further comprising a fourth magnetic layer disposed above the second non-magnetic layer, wherein the fourth magnetic layer is capable of generating a fourth magnetic field and has a fourth magnetization in a fourth direction, and the fourth direction is identical to the first direction.

9. The piezoelectric device according to claim 1, further comprising an upper magnetic structure disposed above the second magnetic layer and a lower magnetic structure disposed below the first magnetic layer, wherein the upper magnetic structure and the lower magnetic structure respectively having a super lattice structure comprising a plurality of magnetic layers and a plurality of non-magnetic layers, wherein each of the magnetic layer and each of the non-magnetic layer are alternately arranged.

10. The piezoelectric device according to claim 1, wherein the piezoelectric layer has a thickness of about 5 nm to about 300 nm.

11. The piezoelectric device according to claim 10, wherein the piezoelectric layer comprises at least one material selected from the group consisting of SiO₂, TiO₂, BaTiO₃, PbTiO₃, AlN, ZnO and PbZrTiO₃.

12. The piezoelectric device according to claim 1, wherein the first magnetic layer has a thickness of about 1 nm to about 200 nm.

13. The piezoelectric device according to claim 12, wherein the first magnetic layer comprises a ferromagnetic material.

14. The piezoelectric device according to claim 13, wherein the ferromagnetic material comprises at least a metal selected from the group consisting of Fe, Co, and Ni.

15. The piezoelectric device according to claim 1, wherein the first magnetic layer is made of a material having a formula of Niₙ(Fe_{y}Co_{10-y})₁₋ₙ, wherein n is a number from 0 to 1, and y is a number from 0 to 1.

16. The piezoelectric device according to claim 1, wherein the first magnetic layer is made of a Nd—Fe—Co alloy having a formula of Ndₓ(Fe_{y}Co_{1-y})₁₋ₓ, wherein x is a number from about 0.1 to about 0.35, and y is a number from 0 to 1.

17. The piezoelectric device according to claim 1, wherein the first magnetic layer is made of a Tb—Fe—Co alloy having a formula of Tbₘ(Fe_{y}Co_{1-y})₁₋ₘ, wherein m is a number from about 0.10 to about 0.22 and from about 0.25 to about 0.35, and y is a number from 0 to 1.

18. The piezoelectric device according to claim 1, wherein the first magnetic layer has a first magnetization in a first direction and the second magnetic layer has a second magnetization in a second direction, and the first direction is opposite to the second direction.
